(19) United States
(12) Patent Application Publication
(10) Pub. No.: US 2016/0260470 A1
(43) Pub. Date: Sep. 8, 2016

(54) SEMICONDUCTOR DEVICE AND SEMICONDUCTOR SYSTEM

(71) Applicant: SK hynix Inc., Icheon-si Gyeonggi-do (KR)

(72) Inventors: Jung Hwan JI, Hwaseong-si Gyeonggi-do (KR); Geun Il LEE, Yongin-si Gyeonggi-do (KR)

(21) Appl. No.: 14/717,072

(22) Filed: May 20, 2015

(30) Foreign Application Priority Data
Mar. 5, 2015 (KR) 10-2015-0031283

(51) Int. Cl. G11C 11/4096; G11C 11/408; G11C 11/4074; G11C 11/406

(52) U.S. Cl. CPC G11C 11/4096; G11C 11/406; G11C 11/408; G11C 11/4074

(57) ABSTRACT

A semiconductor system may include a first semiconductor configured to output a command signal and an address signal. The semiconductor system may include a second semiconductor device configured to include a first operation circuit including a first MOS transistor and a second operation circuit including a second MOS transistor. The first MOS transistor and the second MOS transistor may be turned on in response to a first internal command signal when a first operation is executed according to the command signal. The first MOS transistor may be turned on in response to a period signal generated from the address signal when a second operation is executed according to the command signal.

### CROSS-REFERENCE TO RELATED APPLICATION

The present application claims priority under 35 U.S.C 119(a) to Korean Application No. 10-2015-0031283, filed on Mar. 5, 2015, in the Korean Intellectual Property Office, which is incorporated herein by reference in its entirety as set forth in full.

### BACKGROUND

1. Technical Field

Embodiments of the present disclosure generally relate to semiconductor integrated circuits and, more particularly, to semiconductor device and semiconductor system controlling levels of a plurality of internal voltages.

2. Related Art

Semiconductor devices execute a write operation to store data internally within the semiconductor device. Semiconductor devices execute a read operation to output the stored data from the semiconductor device. Semiconductor devices may execute a refresh operation to retain the stored data.

The write operation, the read operation, and the refresh operation are executed respectively by decoding commands supplied from an external device in communication with the semiconductor device. Operations of circuits related to the write operation and the read operation are terminated when the refresh operation is executed.

A power supply voltage VDD and a ground voltage VSS are supplied to MOS transistors included in circuits related to the write operation and the read operation even though the write operation and the read operation are terminated. A continuous supply of the power supply voltage VDD and the ground voltage VSS may cause the premature degradation of the MOS transistors.

### SUMMARY

In an embodiment, there may be provided a semiconductor system. The semiconductor system may include a first semiconductor configured to output a command signal and an address signal. The semiconductor system may include a second semiconductor device configured to include a first operation circuit comprising a first MOS transistor and a second operation circuit comprising a second MOS transistor. The first MOS transistor and the second MOS transistor may be turned on in response to a first internal command signal when a first operation is executed according to the command signal. The first MOS transistor may be turned on in response to a period signal generated from the address signal when a second operation is executed according to the command signal.

In an embodiment, there may be provided a semiconductor system. The semiconductor system may include a first semiconductor device configured to output a command signal. The semiconductor system may include a second semiconductor device configured to include a first operation circuit comprising a first MOS transistor and a second operation circuit comprising a second MOS transistor. The first MOS transistor and the second MOS transistor may be turned on in response to a first internal command signal when a first operation is executed according to the command signal. The first MOS transistor may be turned on in response to a period signal generated when a second operation is executed according to the command signal.

In an embodiment, there may be provided a semiconductor system. The semiconductor system may include a controller and a semiconductor device. The controller may generate a clock signal, an external control signal, a command signal, and an address signal. The semiconductor device may include an internal address generator, and the internal address generator may generate first and second address latch signals from first and second internal clock signals generated from the clock signal in response to the external control signal and may latch the address signal in response to the first and second address latch signals to generate a synthesized internal address signal.

### BRIEF DESCRIPTION OF THE DRAWINGS

FIG. 1 is a block diagram illustrating a representation of an example of a semiconductor system according to an embodiment.

FIG. 2 is a circuit diagram illustrating a representation of an example of an operation pulse selection unit included in the semiconductor system of FIG. 1.

FIG. 3 is a circuit diagram illustrating a representation of an example of an operation pulse transmission control unit included in the semiconductor system of FIG. 1.

FIG. 4 is a block diagram illustrating a representation of an example of a semiconductor system according to an embodiment.

FIG. 5 is a circuit diagram illustrating a representation of an example of an operation pulse selection unit included in the semiconductor system of FIG. 4.

FIG. 6 is a circuit diagram illustrating a representation of an example of an operation pulse transmission control unit included in the semiconductor system of FIG. 4.

FIG. 7 is a block diagram illustrating a representation of an example of a semiconductor system according to an embodiment.

FIG. 8 illustrates a block diagram of an example of a representation of a system employing a semiconductor system and/or semiconductor device in accordance with the various embodiments discussed above with relation to FIGS. 1-7.

### DETAILED DESCRIPTION

Various embodiments will be described hereinafter with reference to the accompanying drawings. However, the embodiments described herein are for illustrative purposes only and are not intended to limit the scope of the application.

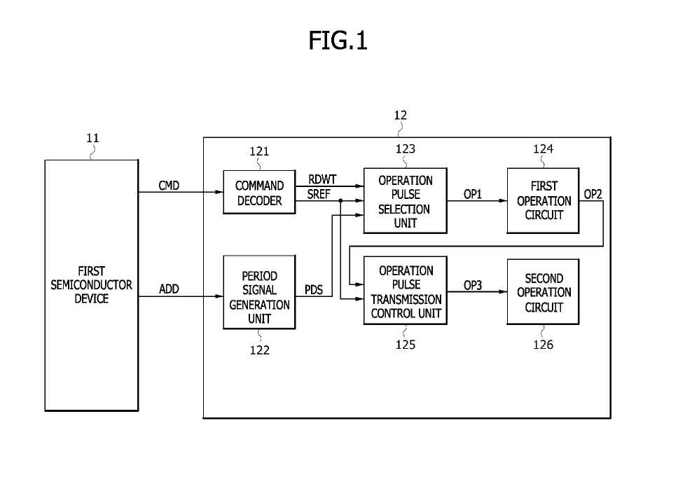

Referring to FIG. 1, a semiconductor system according to an embodiment may include a first semiconductor device 11 and a second semiconductor device 12.

The first semiconductor device 11 may apply a command signal CMD and an address signal ADD to the second semiconductor device 12. In various embodiments, the command signal CMD and the address signal ADD can be transmitted through the same signal lines.

The second semiconductor device 12 may include a command decoder 121, a period signal generation unit 122, and an operation pulse selection unit 123. The second semiconductor device 12 may include a first operation circuit 124, an operation pulse transmission control unit 125, and a second operation circuit 126.

The command decoder 121 may decode the command signal CMD inputted from the first semiconductor device 11. The command decoder 121 may generate a first internal command signal RDWT and a second internal command signal SREF. The first internal command signal RDWT may include at least one pulse for executing either a read operation or a write operation of the second semiconductor device 12. The second internal command signal SREF can be enabled for executing a refresh operation of the second semiconductor device 12. In an embodiment, the first internal command signal RDWT can be enabled for executing various internal operations different from the read operation and the write operation, and the second internal command signal SREF can be enabled for executing an internal operation different from the refresh operation.

The period signal generation unit 122 may receive the address signal ADD to generate a period signal PDS. The period signal PDS may include pulses. The pulses may be periodically created. A level combination and the number of the address signal inputted to generate the period signal PDS may be set differently according to the various embodiments.

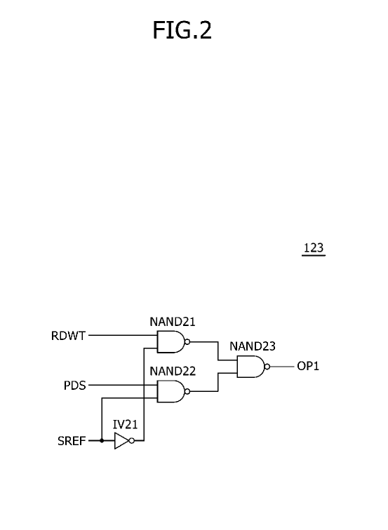

The operation pulse selection unit 123 may transmit the first internal command signal RDWT or the period signal PDS as a first operation pulse OP1 in response to the second internal command signal SREF. For example, the operation pulse selection unit 123 may transmit the period signal PDS as the first operation pulse OP1 when the second internal command signal SREF is enabled, and the first internal command signal RDWT as the first operation pulse OP1 when the second internal command signal SREF is disabled. A configuration and operation of the pulse selection unit 123 will be described later referring to FIG. 2.

The first operation circuit 124 may set an internal circuit for executing the read operation or the write operation. The first operation circuit 124 may include at least one MOS transistor. The MOS transistor included in the first operation circuit 124 may be turned on in response to the first operation pulse OP1 generated from first internal command signal RDWT when the read operation or the write operation is executed. The MOS transistor included in the first operation circuit 124 may be turned on periodically in response to the first operation pulse OP1 generated from the period signal PDS when the refresh operation is executed. The first operation circuit 124 may generate the second operation pulse OP2 from the first operation pulse OP1.

The first operation circuit 124 may output the first operation pulse OP1 as the second operation pulse OP2 or buffer the first operation pulse OP1 to generate the second operation pulse OP2. The second operation pulse OP2 may comprise all pulses included in the first operation pulse OP1.

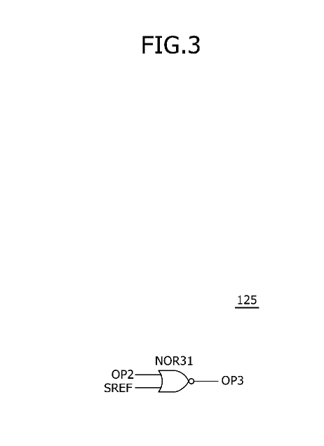

The operation pulse transmission control unit 125 may control the transmission of the second operation pulse OP2 as the third operation pulse OP3 in response to the second internal command signal SREF. For example, the operation pulse transmission control unit 125 may terminate the transmission of the second operation pulse OP2 as the third operation pulse OP3 when the second internal command signal SREF is enabled, and may transmit the second operation pulse OP2 as the third operation pulse OP3 when the second internal command signal SREF is disabled. The operation pulse transmission control unit 125 may set the third operation pulse OP3 to have a predetermined logic level when the second internal command signal SREF is enabled. A configuration and operation of the operation pulse transmission control unit 125 will be described later referring to FIG. 3.

The second operation circuit 126 may set an internal circuit for executing the read operation or the write operation. The second operation circuit 126 may comprise at least one MOS transistor. The MOS transistor included in the second operation circuit 126 may be turned on in response to the third operation pulse OP3 generated from first internal command signal RDWT when the read operation or the write operation is executed. The MOS transistor comprised in the second operation circuit 126 may maintain a turned off state in response to the third operation pulse OP3 set to have the predetermined logic level when the refresh operation is executed.

Referring to FIG. 2, the operation pulse selection unit 123 may comprise, for example, an inverter IV21 and NAND gates NAND 21, NAND22 and NAND23. The operation pulse selection unit 123 may transmit the period signal PDS as a first operation pulse OP1 while the second internal command signal SREF having a logic “high” level is inputted to execute the refresh operation. The operation pulse selection unit 123 may transmit the first internal command signal RDWT as a first operation pulse OP1 while the second internal command signal SREF having a logic “low” level is inputted to terminate the refresh operation.

Referring to FIG. 3, the operation pulse transmission control unit 125 may include, for example, a NOR gate NOR31. The operation pulse transmission control unit 125 may terminate the transmission of the second operation pulse OP2 as the third operation pulse OP3, and set the third operation pulse OP3 to have a logic “low” level while the second internal command signal SREF having a logic “high” level is inputted to execute the refresh operation. The operation pulse transmission control unit 125 may transmit the second operation pulse OP2 as the third operation pulse OP3 while the second internal command signal SREF having a logic “low” level is inputted to terminate the refresh operation.

An operation of the semiconductor system illustrated in FIGS. 1, 2, and 3 will be described hereinafter in conjunction with an example in which the read operation or the write operation is executed and an example in which the refresh operation is executed.

The command decoder 121 may decode the command signal CMD to generate the first internal command signal RDWT when the read operation or the write operation is executed. The MOS transistor included in the first operation circuit 124 may be turned on in response to the first operation pulse OP1 generated from first internal command signal RDWT to execute the read operation or the write operation. The first operation pulse OP1 may be transmitted to the second operation pulse OP2, and the second operation pulse OP2 may be transmitted as the third operation pulse OP3. The MOS transistor included in the second operation circuit 126 may be turned on in response to the third operation pulse OP3 to execute the read operation or the write operation.

The command decoder 121 may decode the command signal CMD to generate the second internal command signal SREF when the refresh operation is executed. The MOS transistor comprised in the first operation circuit 124 may be turned on periodically in response to the first operation pulse OP1 generated from the period signal PDS to execute the refresh operation. The third operation pulse OP3 may be set to have a logic low level. The MOS transistor comprised in the second operation circuit 126 may maintain a turned off state in response to the third operation pulse OP3 set to have the logic low level to execute the refresh operation.

In the semiconductor system according to an embodiment, the MOS transistor included in the first operation circuit 124 may be turned on periodically to prevent degradation when the refresh operation is executed. The MOS transistor comprised in the second operation circuit 126 may maintain a turned off state because the second operation circuit 126 may terminate operation when the refresh operation is executed.

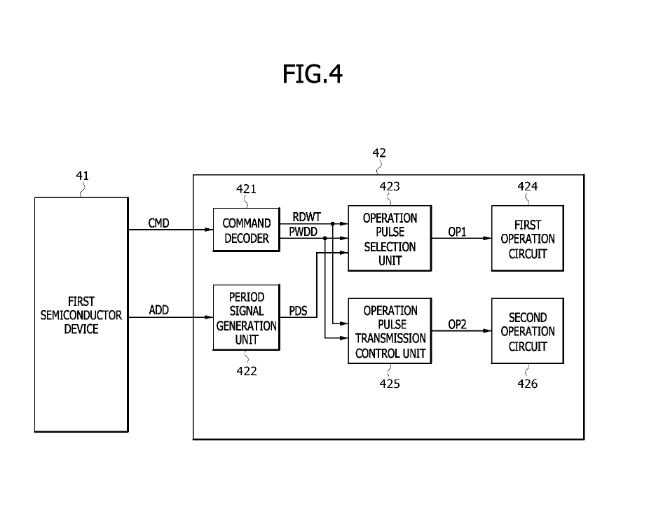

Referring to FIG. 4, a semiconductor system according to an embodiment may include a first semiconductor device 41 and a second semiconductor device 42.

The first semiconductor device 41 may transmit a command signal CMD and an address signal ADD to the second semiconductor device 42. In various embodiments, the command signal CMD and an address signal ADD can be transmitted through the same signal lines.

The second semiconductor device 42 may include a command decoder 421, a period signal generation unit 422, and an operation pulse selection unit 423. The second semiconductor device 42 may include a first operation circuit 424, an operation pulse transmission control unit 425, and a second operation circuit 426.

The command decoder 421 may decode the command signal CMD inputted from the first semiconductor device 41. The command decoder 421 may generate a first internal command signal RDWT and a second internal command signal PWDD. The first internal command signal RDWT may include at least one pulse for executing either a read operation or a write operation of the second semiconductor device 42. The second internal command signal PWDD can be enabled for executing a power down mode operation of the second semiconductor device 42. In an embodiment, the first internal command signal RDWT can be enabled for executing various internal operations different from the read operation and the write operation, and the second internal command signal PWDD can be enabled for executing an internal operation different from the power down mode operation.

The period signal generation unit 422 may receive the address signal ADD to generate a period signal PDS. The period signal PDS may include pulses. The pulses may be periodically created. A level combination and the number of the address signal inputted to generate the period signal PDS may be set to differently according to the various embodiments.

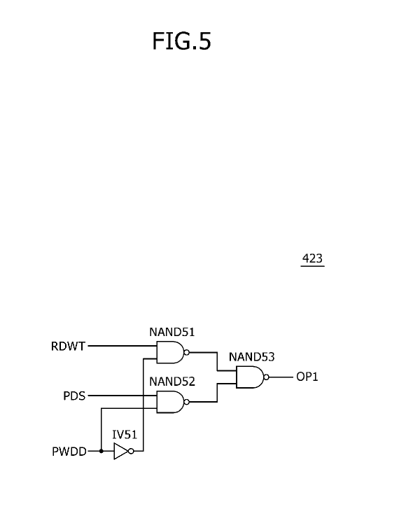

The operation pulse selection unit 423 may transmit the first internal command signal RDWT or the period signal PDS as a first operation pulse OP1 in response to the second internal command signal PWDD. For example, the operation pulse selection unit 423 may transmit the period signal PDS as the first operation pulse OP1 when the second internal command signal PWDD is enabled, and the first internal command signal RDWT as the first operation pulse OP1 when the second internal command signal PWDD is disabled. A configuration and operation of the pulse selection unit 423 will be described later referring to FIG. 5.

The first operation circuit 424 may set an internal circuit for executing the read operation or the write operation. The first operation circuit 424 may include at least one MOS transistor. The MOS transistor included in the first operation circuit 424 may be turned on in response to the first operation pulse OP1 generated from first internal command signal RDWT when the read operation or the write operation is executed. The MOS transistor included in the first operation circuit 424 may be turned on periodically in response to the first operation pulse OP1 generated from the period signal PDS when the power down mode operation is executed.

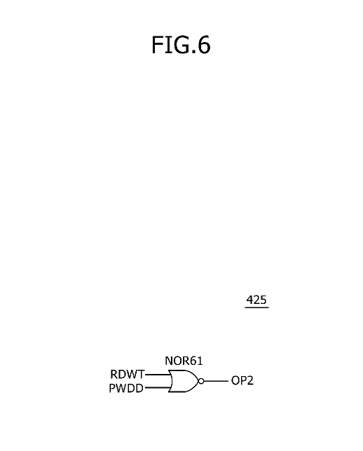

The operation pulse transmission control unit 425 may control the transmission of the first internal command signal RDWT as the second operation pulse OP2 in response to the second internal command signal PWDD. For example, the operation pulse transmission control unit 425 may terminate the transmission of the first internal command signal RDWT as the second operation pulse OP2 when the second internal command signal PWDD is enabled, and may transmit the first internal command signal RDWT as the second operation pulse OP2 when the second internal command signal PWDD is disabled. The operation pulse transmission control unit 425 may set the second operation pulse OP2 to have a predetermined logic level when the second internal command signal PWDD is enabled. A configuration and operation of the operation pulse transmission control unit 425 will be described later referring to FIG. 6.

The second operation circuit 426 may set an internal circuit for executing the read operation or the write operation. The second operation circuit 426 may comprise at least one MOS transistor. The MOS transistor included in the second operation circuit 426 may be turned on in response to the second operation pulse OP2 generated from first internal command signal RDWT when the read operation or the write operation is executed. The MOS transistor comprised in the second operation circuit 426 may maintain a turned off state in response to the second operation pulse OP2 set to have the predetermined logic level when the refresh operation is executed.

Referring to FIG. 5, the operation pulse selection unit 423 may comprise, for example, an inverter IV51 and NAND gates NAND51, NAND52 and NAND53. The operation pulse selection unit 423 may transmit the period signal PDS as a first operation pulse OP1 while the second internal command signal PWDD having a logic “high” level is inputted to execute the power down mode operation. The operation pulse selection unit 423 may transmit the first internal command signal RDWT as a first operation pulse OP1 while the second internal command signal PWDD having a logic “low” level is inputted to terminate the power down mode operation.

Referring to FIG. 6, the operation pulse transmission control unit 425 may include, for example, a NOR gate NOR61. The operation pulse transmission control unit 425 may terminate the transmission of the first internal command signal RDWT as the second operation pulse OP2 while the second internal command signal PWDD having a logic “high” level is inputted to execute the power down mode operation. The operation pulse transmission control unit 425 may transmit the first internal command signal RDWT as the second operation pulse OP2 while the second internal command signal PWDD having a logic “low” level is inputted to terminate the power down mode operation.

An operation of the semiconductor system illustrated in FIGS. 4, 5, and 6 will be described hereinafter in conjunction with an example in which the read operation or the write operation is executed and an example in which the power down mode operation is executed.

The command decoder 421 may decode the command signal CMD to generate the first internal command signal RDWT when the read operation or the write operation is executed. The MOS transistor included in the first operation circuit 424 may be turned on in response to the first operation pulse OP1 generated from first internal command signal RDWT to execute the read operation or the write operation. The first internal command signal RDWT may be transmitted as the second operation pulse OP2. The MOS transistor included in the second operation circuit 426 may be turned on in response to the second operation pulse OP2 to execute the read operation or the write operation.

The command decoder 421 may decode the command signal CMD to generate the second internal command signal PWDD when the power down mode operation is executed. The MOS transistor comprised in the first operation circuit 424 may be turned on periodically in response to the first operation pulse OP1 generated from the period signal PDS to execute the power down mode operation. The second operation pulse OP2 may be set to have a logic low level. The MOS transistor comprised in the second operation circuit 426 may maintain a turned off state in response to the second operation pulse OP2 set to have the logic low level to execute the power down mode operation.

In the semiconductor system according to an embodiment, the MOS transistor included in the first operation circuit 424 may be turned on periodically to prevent degradation when the power down mode operation is executed. The MOS transistor comprised in the second operation circuit 426 may maintain a turned off state because the second operation circuit 426 may terminate operation when the power down mode operation is executed.

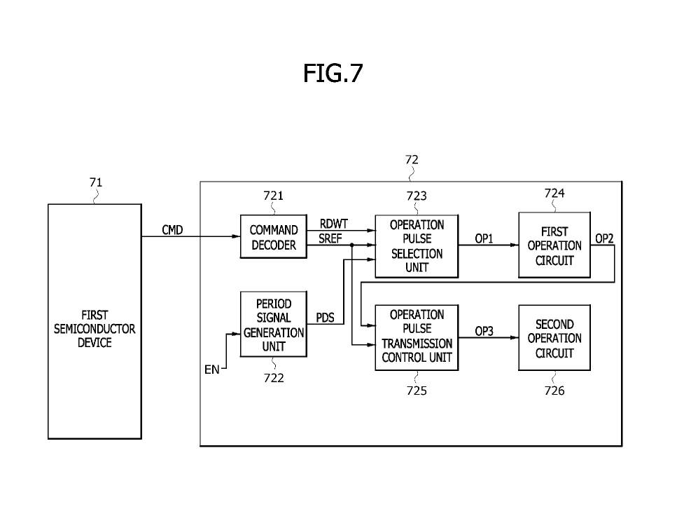

Referring to FIG. 7, a semiconductor system according to an embodiment may include a first semiconductor device 71 and a second semiconductor device 72.

The first semiconductor device 71 may transmit a command signal CMD to the second semiconductor device 72.

The second semiconductor device 72 may include a command decoder 721, a period signal generation unit 722, and an operation pulse selection unit 723. The second semiconductor device 72 may include a first operation circuit 724, an operation pulse transmission control unit 725, and a second operation circuit 726.

The command decoder 721 may decode the command signal CMD inputted from the first semiconductor device 71. The command decoder 721 may generate a first internal command signal RDWT and a second internal command signal SREF. The first internal command signal RDWT may include at least one pulse for executing either a read operation or a write operation of the second semiconductor device 72. The second internal command signal SREF can be enabled for executing a refresh operation of the second semiconductor device 72. In an embodiment, the first internal command signal RDWT can be enabled for executing various internal operations different from the read operation and the write operation, and the second internal command signal SREF can be enabled for executing an internal operation different from the refresh operation.

The period signal generation unit 722 may generate a period signal PDS including pulses. The pulses may be periodically created in response to an enable signal EN. The enable signal EN may be supplied from an outside of the second semiconductor device 72 or generated in the semiconductor device 72 according to the various embodiments.

The operation pulse selection unit 723 may transmit the first internal command signal RDWT or the period signal PDS as a first operation pulse OP1 in response to the second internal command signal SREF. For example, the operation pulse selection unit 723 may transmit the period signal PDS as the first operation pulse OP1 when the second internal command signal SREF is enabled, and the first internal command signal RDWT as the first operation pulse OP1 when the second internal command signal SREF is disabled.

The first operation circuit 724 may set an internal circuit for executing the read operation or the write operation. The first operation circuit 724 may include at least one MOS transistor. The MOS transistor included in the first operation circuit 724 may be turned on in response to the first operation pulse OP1 generated from first internal command signal RDWT when the read operation or the write operation is executed. The MOS transistor included in the first operation circuit 724 may be turned on periodically in response to the first operation pulse OP1 generated from the period signal PDS when the refresh operation is executed. The first operation circuit 724 may generate the second operation pulse OP2 from the first operation pulse OP1. The first operation circuit 724 may output the first operation pulse OP1 as the second operation pulse OP2, or buffer the first operation pulse OP1 to generate the second operation pulse OP2. The second operation pulse OP2 may comprise all pulses included in the first operation pulse OP1.

The operation pulse transmission control unit 725 may control the transmission of the second operation pulse OP2 as the third operation pulse OP3 in response to the second internal command signal SREF. For example, the operation pulse transmission control unit 725 may terminate the transmission of the second operation pulse OP2 as the third operation pulse OP3 when the second internal command signal SREF is enabled, and may transmit the second operation pulse OP2 as the third operation pulse OP3 when the second internal command signal SREF is disabled. The operation pulse transmission control unit 725 may set the third operation pulse OP3 to have a predetermined logic level when the second internal command signal SREF is enabled.

The second operation circuit 726 may set an internal circuit for executing the read operation or the write operation. The second operation circuit 726 may comprise at least one MOS transistor. The MOS transistor included in the second operation circuit 726 may be turned on in response to the third operation pulse OP3 generated from first internal command signal RDWT when the read operation or the write operation is executed. The MOS transistor comprised in the second operation circuit 726 may maintain a turned off state in response to the third operation pulse OP3 set to have the predetermined logic level when the refresh operation is executed.

The semiconductor system illustrated in FIG. 7 may be realized to have substantially the same configuration as the semiconductor system illustrated in FIG. 1. Thus, a configuration and operation of the semiconductor system will be omitted hereinafter.

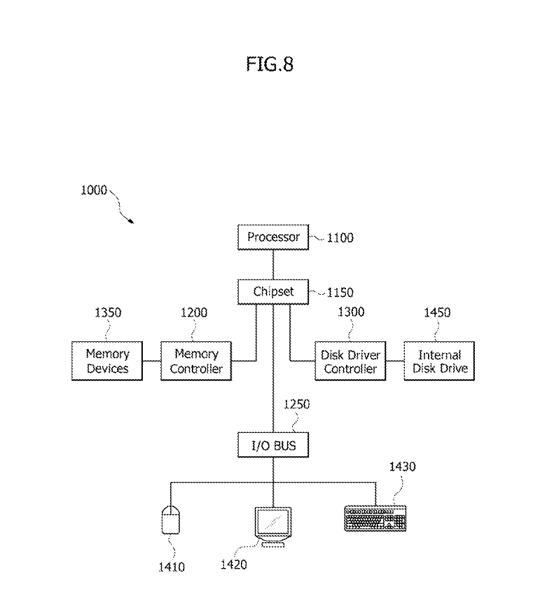

The semiconductor system and/or semiconductor device discussed above (see FIGS. 1-7) are particular useful in the design of memory devices, processors, and computer systems. For example, referring to FIG. 8, a block diagram of a system employing the semiconductor system and/or semiconductor device in accordance with the various embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one semiconductor system and/or semiconductor device as discussed above with reference to FIGS. 1-7. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor system and/or semiconductor device as discussed above with relation to FIGS. 1-7, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 8 is merely one example of a system employing the semiconductor system and/or semiconductor device as discussed above with relation to FIGS. 1-7. In alternate embodiments, such as cellular phones or digital cameras, the components may differ from the embodiments illustrated in FIG. 8.

What is claimed is:

1. A semiconductor system comprising:
a first semiconductor device configured to output a command signal and an address signal; and
a second semiconductor device configured to include a first operation circuit comprising a first MOS transistor and a second operation circuit comprising a second MOS transistor,
wherein the first MOS transistor and the second MOS transistor are turned on in response to a first internal command signal when a first operation is executed according to the command signal, and the first MOS transistor is turned on in response to a period signal generated from the address signal when a second operation is executed according to the command signal.

2. The semiconductor system of claim 1, wherein the first operation includes a read operation or a write operation.

3. The semiconductor system of claim 1, wherein the second operation includes a refresh operation.

4. The semiconductor system of claim 1, wherein the second operation includes a power down mode operation.

5. The semiconductor system of claim 1, wherein the second semiconductor device comprises an operation pulse selection unit configured to transmit the first internal command signal as a first operation pulse when the first operation is executed and to transmit the period signal as the first operation pulse when the second operation is executed, and the first MOS transistor is turned on in response to the first operation pulse.

6. The semiconductor system of claim 5, wherein the first operation circuit transmits the first operation pulse as a second operation pulse.

7. The semiconductor system of claim 6, wherein the second semiconductor device further comprises:
an operation pulse transmission control unit configured to transmit the second operation pulse as a third operation pulse when the first operation is executed and set the third operation pulse to have a predetermined logic level when the second operation is executed.

8. The semiconductor system of claim 7, wherein the second MOS transistor is turned on in response to the third operation pulse.

9. The semiconductor system of claim 5, wherein the second semiconductor device further comprises:
an operation pulse transmission control unit configured to transmit the first internal command signal as the second operation pulse when the first operation is executed and set the second operation pulse to have a predetermined logic level when the second operation is executed.

10. The semiconductor system of claim 9, wherein the second MOS transistor is turned on in response to the second operation pulse.

11. A semiconductor system comprising:
a first semiconductor device configured to output a command signal; and
a second semiconductor device configured to include a first operation circuit comprising a first MOS transistor and a second operation circuit comprising a second MOS transistor,
wherein the first MOS transistor and the second MOS transistor are turned on in response to a first internal command signal when a first operation is executed according to the command signal, and the first MOS transistor is turned on in response to a period signal generated when a second operation is executed according to the command signal.

12. The semiconductor system of claim 11, wherein the first operation includes a read operation or a write operation.

13. The semiconductor system of claim 11, wherein the second operation includes a refresh operation or a power down mode operation.

14. The semiconductor system of claim 11,
wherein the second semiconductor device comprises an operation pulse selection unit configured to transmit the first internal command signal as a first operation pulse when the first operation is executed and to transmit the period signal as the first operation pulse when the second operation is executed, and
wherein the first MOS transistor is turned on in response to the first operation pulse.

15. The semiconductor system of claim 14, wherein the first operation circuit transmits the first operation pulse as a second operation pulse.

16. The semiconductor system of claim 15,
wherein the second semiconductor device further comprises an operation pulse transmission control unit configured to transmit the second operation pulse as a third operation pulse when the first operation is executed and set the third operation pulse to have a predetermined logic level when the second operation is executed, and
wherein the second MOS transistor is turned on in response to the third operation pulse.

17. The semiconductor system of claim 14,
wherein the second semiconductor device further comprises an operation pulse transmission control unit configured to transmit the first internal command signal as the second operation pulse when the first operation is executed and set the second operation pulse to have a predetermined logic level when the second operation is executed, and
wherein the second MOS transistor is turned on in response to the second operation pulse.

18. A semiconductor device comprising:
an operation pulse selection unit configured to transmit a first internal command signal generated by decoding a command signal to a first operation pulse when the first operation is executed and a period signal generated by decoding the command signal to the first operation pulse when the second operation is executed; and
an operation circuit configured to include a MOS transistor,
wherein the MOS transistor is turned on in response to the operation pulse.

19. The semiconductor device of claim 18, wherein the first operation includes a read operation or a write operation.

20. The semiconductor device of claim 18, wherein the second operation includes a refresh operation or a power down mode operation.
